(19) United States
(12) Patent Application Publication
(10) Pub. No.: US 2026/0107563 A1
(43) Pub. Date: Apr. 16, 2026

(54) SEMICONDUCTOR DEVICE

(71) Applicant: SAMSUNG ELECTRONICS CO., LTD., Suwon-si (KR)

(72) Inventors: Seongpil CHANG, Suwon-si (KR); Dongkyu Kim, Suwon-si (KR); Sea Hoon Lee, Suwon-si (KR)

(73) Assignee: SAMSUNG ELECTRONICS CO., LTD., Suwon-si (KR)

(21) Appl. No.: 19/172,113

(22) Filed: Apr. 7, 2025

(30) Foreign Application Priority Data
Oct. 15, 2024 (KR) 10-2024-0140343

(51) Int. Cl. H10D 84/83; H10D 62/10; H10D 62/60; H10D 64/27

(52) U.S. Cl. CPC H10D 84/83138; H10D 62/124; H10D 62/60; H10D 64/518; H10D 84/8312

(57) ABSTRACT

A semiconductor device includes a substrate; an active region on the substrate and extending in a first direction; a device isolation film around the active region in the substrate; a first gate electrode extending on the active region in a second direction that intersects the first direction; a second gate electrode extending on the active region in the second direction and spaced apart from the first gate electrode in the first direction; a first connection gate electrode extending in the first direction and connected to a first end of the first gate electrode and a first end of the second gate electrode; and a source/drain region in the active region at a side of the first gate electrode.

### CROSS-REFERENCE TO RELATED APPLICATION

This application claims priority to Korean Patent Application No. 10-2024-0140343, filed in the Korean Intellectual Property Office on Oct. 15, 2024, the disclosure of which is incorporated by reference herein in its entirety.

### BACKGROUND

### 1. Field

The present disclosure relates to a semiconductor device.

### 2. Description of Related Art

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of electronic devices are increasing. Accordingly, high-performance characteristics of the semiconductor devices are essentially required, and the integration density of the semiconductor devices is increasing to meet these requirements. Various methods for forming semiconductor devices having excellent performance and improved integration density are being studied.

### SUMMARY

One or more embodiments of the present disclosure provide a semiconductor device which may have improved electrical characteristics and reliability.

Further, one or more embodiments of the present disclosure provide a semiconductor device in which a connection gate electrode is connected to a plurality of gate electrodes such that on-current characteristics of the semiconductor device may be improved.

Further, one or more embodiments of the present disclosure, provide a semiconductor device in which a width of a central portion of a gate electrode of at least some of a plurality of gate electrodes is greater than the width of a peripheral portion such that the off-current characteristics of the semiconductor device may be improved.

According to an aspect of the disclosure, a semiconductor device includes: a substrate; an active region on the substrate and extending in a first direction; a device isolation film around the active region in the substrate; a first gate electrode extending on the active region in a second direction that intersects the first direction; a second gate electrode extending on the active region in the second direction and spaced apart from the first gate electrode in the first direction; a first connection gate electrode extending in the first direction and connected to a first end of the first gate electrode and a first end of the second gate electrode; and a source/drain region in the active region at a side of the first gate electrode.

According to an aspect of the disclosure, a semiconductor device includes: a substrate; an active region extending on the substrate in a first direction; a device isolation film around the active region in the substrate; an isolation impurity region in the substrate under the device isolation film and around the active region, wherein the isolation impurity region includes a first horizontal portion extending in the first direction, a second horizontal portion extending in the first direction, a first vertical portion extending in a second direction that intersects the first direction, and a second vertical portion extending in the second direction; a plurality of gate electrodes extending on the active region in the second direction and spaced apart from each other in the first direction; a first connection gate electrode extending in the first direction and connected to at least a portion of the plurality of gate electrodes; and a second connection gate electrode extending in the first direction, connected to at least a portion of the plurality of gate electrodes, and spaced apart from the first connection gate electrode in the second direction.

According to an aspect of the disclosure, a semiconductor device includes: a substrate; an active region extending on the substrate in a first direction; a device isolation film around the active region in the substrate; an isolation impurity region in the substrate under the device isolation film and around the active region, wherein the isolation impurity region includes a first horizontal portion extending in the first direction, a second horizontal portion extending in the first direction, a first vertical portion extending in a second direction that intersects the first direction, and a second vertical portion extending in the second direction; a first gate electrode extending on the active region in the second direction and adjacent to the first vertical portion of the isolation impurity region; a second gate electrode extending on the active region in the second direction and spaced apart from the first gate electrode in the first direction; a first connection gate electrode extending in the first direction and connected to a first end of the first gate electrode and a first end of the second gate electrode; a second connection gate electrode extending in the first direction and connected to a second end of the first gate electrode and a second end of the second gate electrode; and a source/drain region between the first gate electrode and the first vertical portion of the isolation impurity region, wherein the second gate electrode includes a first portion having a first width in the first direction and a second portion having a second width in the first direction, and the first width is greater than the second width.

According to an aspect of the disclosure, a semiconductor device includes: a substrate; an active region extending on the substrate in a first direction; a device isolation film around the active region in the substrate; an isolation impurity region in the substrate under the device isolation film and around the active region, the isolation impurity region including a first horizontal portion extending in the first direction, a second horizontal portion extending in the first direction, a first vertical portion extending in a second direction that intersects the first direction, and a second vertical portion extending in the second direction; a plurality of gate electrodes extending on the active region in the second direction and spaced apart from each other in the first direction; and a source/drain region in the active region and on at least one side of the plurality of gate electrodes, wherein the plurality of gate electrodes include a first gate electrode closest to the first vertical portion of the isolation impurity region, and a second gate electrode spaced apart from the first gate electrode in the first direction, the second gate electrode includes a first portion having a first width in the first direction and a second portion having a second width in the first direction, and the first width is greater than the second width.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout diagram provided to explain a semiconductor device according to one or more embodiments;

FIG. 2 is an enlarged view provided to explain a region Q1 of FIG. 1;

FIG. 3 is a cross-sectional view taken along line A-A of FIG. 1. FIG. 4 is a cross-sectional view taken along line B-B of FIG. 1.;

FIG. 5 is an example layout diagram provided to explain a semiconductor device according to one or more embodiments;

FIG. 6 is an enlarged view provided to explain a region Q2 of FIG. 5;

FIG. 7 is a cross-sectional view taken along line C-C of FIG. 5;

FIG. 8 is an example layout diagram provided to explain a semiconductor device according to one or more embodiments;

FIG. 9 is an example layout diagram provided to explain a semiconductor device according to one or more embodiments;

FIG. 10 is an example layout diagram provided to explain a semiconductor device according to one or more embodiments;

FIG. 11 is an example layout diagram provided to explain a semiconductor device according to one or more embodiments;

FIG. 12 is an example layout diagram provided to explain the semiconductor device according to one or more embodiments;

FIG. 13 is an example layout diagram provided to explain a semiconductor device according to one or more embodiments; and

FIG. 14 is an example layout diagram provided to explain a semiconductor device according to one or more embodiments.

### DETAILED DESCRIPTION

The terms such as first, second, etc. may be used herein to describe various devices or components, but the devices or components are not limited by these terms. It should be understood that these terms are only used to distinguish one element or component from another element or component. It goes without saying that the first element or component mentioned below may be the second element or component within the technical idea of the present disclosure.

A semiconductor device and a method for manufacturing the same according to example embodiments of the present disclosure will be described in detail below with reference to the drawings. However, embodiments of the present disclosure are not limited to the example embodiments described herein.

It is to be noted that a planar transistor will be illustrated in the drawings as an example of the semiconductor device according to one or more embodiments, but embodiments are not limited thereto. The semiconductor device according to one or more embodiments may include a fin-type transistor (FinFET) including a fin-type pattern-shaped channel region, a transistor including a nanowire or a nanosheet, or a three-dimensional (3D) transistor.

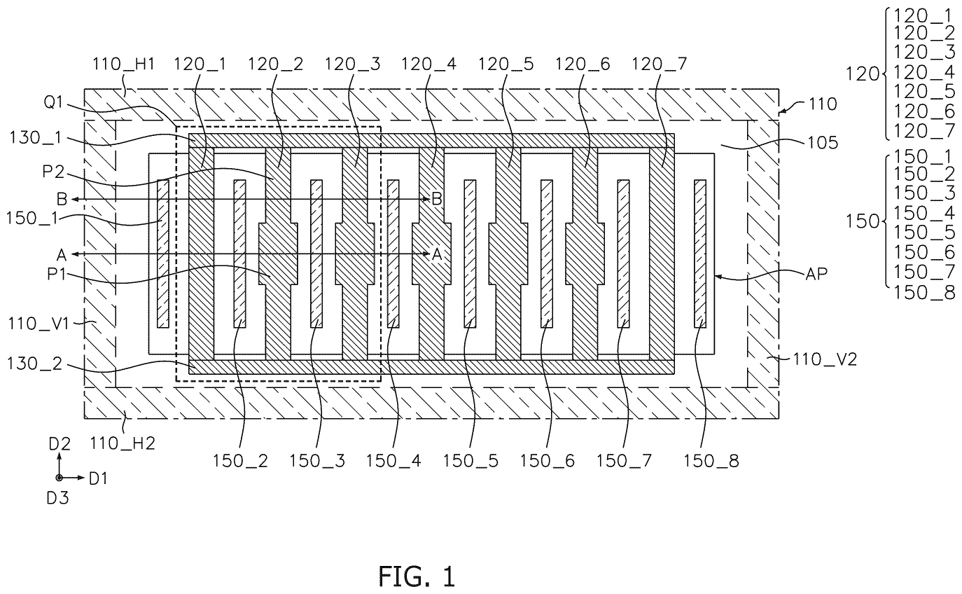

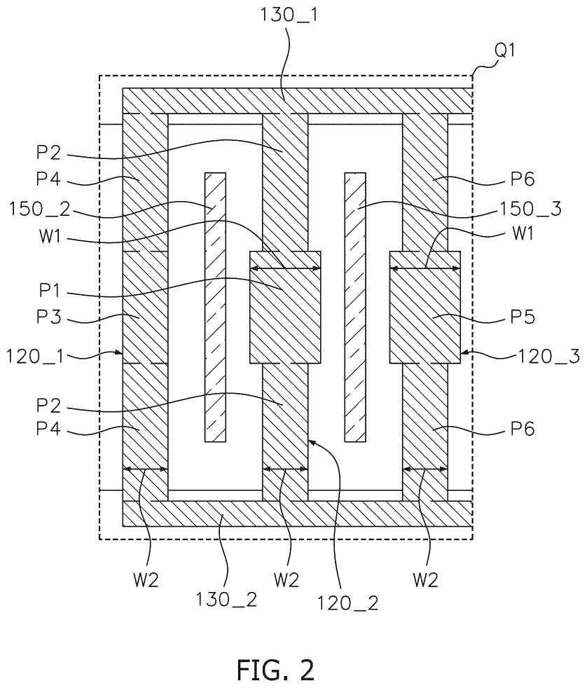

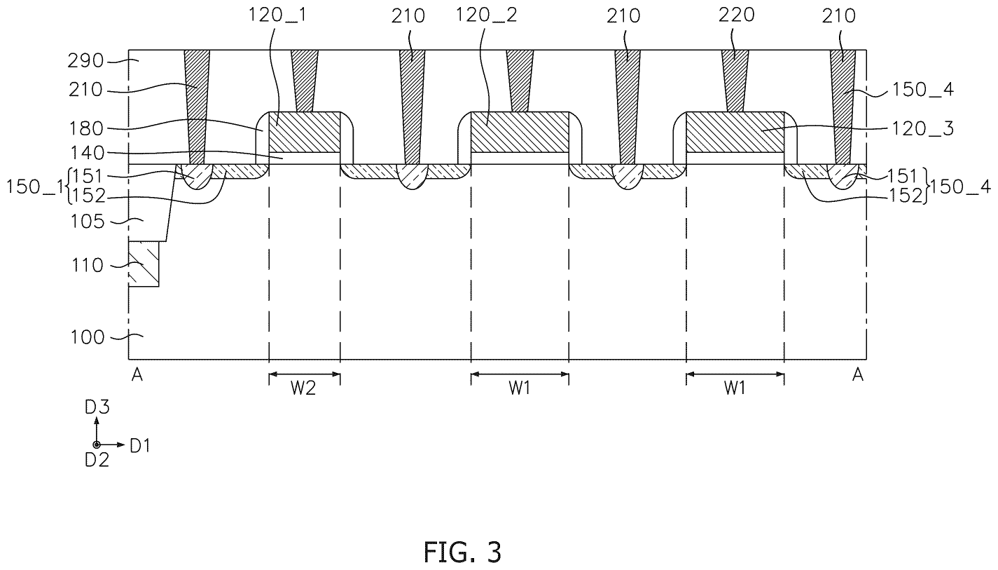

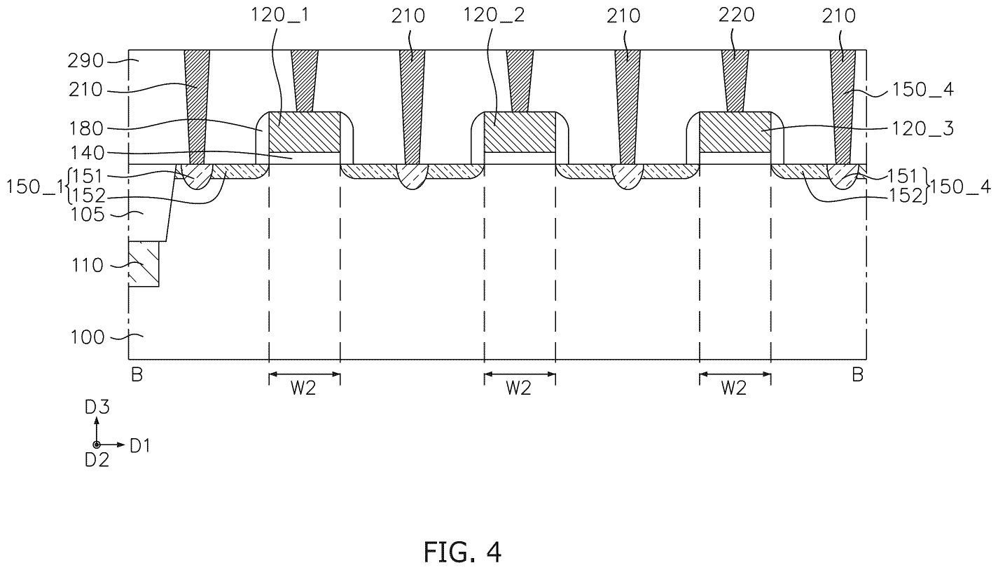

FIG. 1 is an example layout diagram provided to explain a semiconductor device according to one or more embodiments. FIG. 2 is an enlarged view provided to explain a region Q1 of FIG. 1. FIG. 3 is a cross-sectional view taken along line A-A of FIG. 1. FIG. 4 is a cross-sectional view taken along line B-B of FIG. 1.

Referring to FIGS. 1 to 4, the semiconductor device according to one or more embodiments may include a substrate 100, a device isolation film 105, an isolation impurity region 110, an active region AP, a plurality of source/drain regions 150, a plurality of gate electrodes 120, a first connection gate electrode 130_1, a second connection gate electrode 130_2, a gate insulating film 140, a source/drain contact 210, and a gate contact 220.

The substrate 100 may include a base substrate and an epitaxial layer grown on the base substrate, but embodiments are not limited thereto. For example, the substrate 100 may include only a base substrate without an epitaxial layer. The substrate 100 may be a silicon substrate, a gallium arsenic substrate, a silicon germanium substrate, a ceramic substrate, a quartz substrate, a glass substrate for display, or a semiconductor on insulator (SOI) substrate. In the following description, a silicon substrate as an example of the substrate 100 will be described.

In one or more embodiments, the substrate 100 may be doped with a first conductivity type. For example, the first conductivity type may be a p-type. For example, the substrate 100 may include a p-type impurity. However, embodiments are not limited to the above. For example, the first conductivity type may be an n-type.

The active region AP may be disposed on the substrate 100. The active region AP may extend in a first direction D1. The first direction D1 may be a direction parallel to an upper surface of the substrate 100. A second direction D2 may be a direction intersecting the first direction D1. The second direction D2 may be a direction parallel to the upper surface of the substrate 100.

The device isolation film 105 may define the active region AP in the substrate 100. For example, the device isolation film 105 may surround the active region AP when viewed in a plan view. The device isolation film 105 may be disposed in a shallow trench in the substrate 100. The device isolation film 105 may include an insulating material. For example, the device isolation film 105 may include at least one of silicon oxide, silicon nitride, silicon oxynitride, and a combination thereof, but embodiments are not limited thereto.

The isolation impurity region 110 may be formed in the substrate 100. The isolation impurity region 110 may be disposed under the device isolation film 105. The isolation impurity region 110 may overlap with the device isolation film 105 in a third direction D3. The third direction D3 may be perpendicular to the upper surface of the substrate 100. When viewed in a plan view, the isolation impurity region may be spaced apart from the active region AP to surround the active region AP. As illustrated in FIG. 1, the device isolation film 105 may be disposed between the active region AP and the isolation impurity region 110.

The isolation impurity region 110 may be doped with the first conductivity type. For example, the isolation impurity region 110 may include the p-type impurity. Forming the isolation impurity region 110 may involve, for example, an ion implantation process, but embodiments are not limited thereto. The p-type impurity may include, for example, boron (B) or aluminum (Al), but embodiments are not limited thereto. In one or more embodiments, the isolation impurity region 110 may include boron (B).

The isolation impurity region 110 may include a first horizontal portion 110_H1, a second horizontal portion 110_H2, a first vertical portion 110_V1, and a second vertical portion 110_V2.

The first horizontal portion 110_H1 may extend in the first direction D1. The second horizontal portion 110_H2 may extend in the first direction D1 and may be spaced apart from the first horizontal portion 110_H1 in the second direction D2. The first vertical portion 110_V1 may extend in the second direction D2. The second vertical portion 110_V2 may extend in the second direction D2 and may be spaced apart from the first vertical portion 110_V1 in the first direction D1. The first horizontal portion 110_H1 may be connected to the first vertical portion 110_V1 and the second vertical portion 110_V2, and the second horizontal portion 110_H2 may be connected to the first vertical portion 110_V1 and the second vertical portion 110_V2. Lengths of the first horizontal portion 110_H1 and the second horizontal portion 110_H2 may be greater than lengths of the first vertical portion 110_V1 and the second vertical portion 110_V2.

The plurality of gate electrodes 120 may be disposed on the active region AP. When viewed in a plan view, the plurality of gate electrodes 120 may be surrounded by the isolation impurity region AP. The plurality of gate electrodes 120 may include first to seventh gate electrodes 120_1, 120_2, 120_3, 120_4, 120_5, 120_6, and 120_7. Although it is illustrated that the plurality of gate electrodes 120 include seven gate electrodes, this number should be understood as an example. For example, the number of the plurality of gate electrodes 120 may be less than or more than 7.

Each of the first to seventh gate electrodes 120_1, 120_2, 120_3, 120_4, 120_5, 120_6, and 120_7 may extend in the second direction D2. Each of the first to seventh gate electrodes 120_1, 120_2, 120_3, 120_4, 120_5, 120_6, and 120_7 may be spaced apart from each other in the first direction D1. The source/drain regions 150 may be disposed between each of the first to seventh gate electrodes 120_1, 120_2, 120_3, 120_4, 120_5, 120_6, and 120_7.

The first gate electrode 120_1 may be adjacent to one end of the active region AP. For example, the first gate electrode 120_1 of the plurality of gate electrodes 120 may be disposed closest to the first vertical portion 110_V1 of the isolation impurity region 110. The first gate electrode 120_1 may be disposed between the first horizontal portion 110_H1 and the second horizontal portion 110_H2 of the isolation impurity region 110. The first gate electrode 120_1 may be disposed between the first vertical portion 110_V1 of the isolation impurity region 110 and the second gate electrode 120 2.

The second gate electrode 120_2 may be spaced apart from the first gate electrode 120 1 in the first direction D1. The second gate electrode 120_2 may be disposed between the first horizontal portion 110_H1 and the second horizontal portion 110_H2 of the isolation impurity region 110. The second gate electrode 120_2 may be disposed between the first gate electrode 120_1 and the third gate electrode 120_3.

The third gate electrode 120_3 may be spaced apart from the second gate electrode 120_2 in the first direction D1. The third gate electrode 120_3 may be disposed between the first horizontal portion 110_H1 and the second horizontal portion 110_H2 of the isolation impurity region 110. The third gate electrode 120_3 may be disposed between the second gate electrode 120_2 and the fourth gate electrode 120 4.

The second gate electrode 120_2 may include a first portion P1 and a second portion P2. The first portion P1 of the second gate electrode 120_2 may have a first width W1 in the first direction D1. The second portion P2 of the second gate electrode 120_2 may have a second width W2 in the first direction D1. The first width W1 may be greater than the second width W2.

The first portion P1 of the second gate electrode 120_2 may be disposed in a middle portion of the second gate electrode 120_2. For example, a distance from the first portion P1 of the second gate electrode 120_2 to the first connection gate electrode 130_1 and a distance from the first portion P1 to the second connection gate electrode 130_2 may be the same as each other. The second portion P2 of the second gate electrode 120_2 may be disposed between the first portion P1 of the second gate electrode 120_2 and the first connection gate electrode 130_1, and the second portion P2 of the second gate electrode 120_2 may be disposed between the first portion P1 of the second gate electrode 120_2 and the second connection gate electrode 130_2. The second portion P2 of the second gate electrode 120_2 may be in contact with the first connection gate electrode 130_1 and the second connection gate electrode 130_2. The first portion P1 of the second gate electrode 120_2 may protrude further than the second portion P2 in the first direction D1.

The first gate electrode 120_1 may include a third portion P3 and a fourth portion P4. The third portion P3 of the first gate electrode 120_1 may have the second width W2 in the first direction D1. The fourth portion P4 of the first gate electrode 120_1 may have the second width W2 in the first direction D1. That is, the first gate electrode 120_1 may have a constant width (e.g., the second width W2) in the first direction D1. The third portion P3 of the first gate electrode 120_1 may overlap with the first portion P1 of the second gate electrode 120 2 in the first direction D1. The fourth portion P4 of the first gate electrode 120_1 may overlap with the second portion P2 of the second gate electrode 120_2 in the first direction D1.

The third gate electrode 120_3 may include a fifth portion P5 and a sixth portion P6. The fifth portion P5 of the third gate electrode 120_3 may have the first width W1 in the first direction D1. The sixth portion P6 of the third gate electrode 120_3 may have the second width W2 in the first direction D1. The first width W1 may be greater than the second width W2. The fifth portion P5 of the third gate electrode 120_3 may overlap with the first portion P1 of the second gate electrode 120_2 in the first direction D1. The sixth portion P6 of the third gate electrode 120_3 may overlap with the second portion P2 of the second gate electrode 120 2 in the first direction D1. The shape of the third gate electrode 120_3 may be the same as the shape of the second gate electrode 120 2.

Descriptions of fourth to sixth gate electrodes 120_4, 120_5, and 120_6 may be similar to those of the second gate electrode 120_2. Each of the fourth to sixth gate electrodes 120_4, 120_5, and 120_6 may include a portion corresponding to the first portion P1 and the second portion P2 of the second gate electrode 120_2. The shape of each of the fourth to sixth gate electrodes 120_4, 120_5, and 120_6 may be the same as the shape of the second gate electrode 120 2.

The seventh gate electrode 120_7 may be adjacent to the other end of the active region AP. For example, the seventh gate electrode 120_7 of the plurality of gate electrodes 120 may be disposed closest to the second vertical portion 110_V2 of the isolation impurity region 110. The seventh gate electrode 120_7 may be disposed between the first horizontal portion 110_H1 and the second horizontal portion 110_H2 of the isolation impurity region 110. The seventh gate electrode 120_7 may be disposed between the second vertical portion 110_V2 of the isolation impurity region 110 and the sixth gate electrode 120_6. The shape of the seventh gate electrode 120_7 may be the same as the shape of the first gate electrode 120_1.

The length of each of the first to seventh gate electrodes 120_1, 120_2, 120_3, 120_4, 120_5, 120_6, and 120_7 in the second direction D2 may be greater than the length in the second direction D2 of the active region AP. The first gate electrode 120_1 will be described as a representative example. One and the other ends of the first gate electrode 120_1 may protrude further than the active region AP in the second direction D2. One and the other ends of the first gate electrode 120_1 may be disposed on the device isolation film 105. The one end of the first gate electrode 120_1 may be connected to the first connection gate electrode 130_1, and the other end of the first gate electrode 120_1 may be connected to the second connection gate electrode 130_2.

The first connection gate electrode 130_1 may be disposed on the device isolation film 105. The first connection gate electrode 130_1 may be spaced apart from the active region AP in the second direction D2. The first connection gate electrode 130_1 may not overlap with the active region AP in the third direction D3. The first connection gate electrode 130_1 may extend in the first direction D1. One end of the first connection gate electrode 130_1 may not protrude further than the first gate electrode 120_1 in the first direction D1. The other end of the first connection gate electrode 130_1 may not protrude further than the seventh gate electrode 120_7 in the first direction D1. The first connection gate electrode 130_1 may not overlap with a first source/drain region 150_1 and an eighth source/drain pattern 150_8 in the second direction D2.

The first connection gate electrode 130_1 may be connected to each of the first to seventh gate electrodes 120_1, 120_2, 120_3, 120_4, 120_5, 120_6, and 120_7. The first connection gate electrode 130_1 may be connected to one end of each of the first to seventh gate electrodes 120_1, 120_2, 120_3, 120_4, 120_5, 120_6, and 120_7 on the device isolation film 105. A boundary surface between the first connection gate electrode 130_1 and the first to seventh gate electrodes 120_1, 120_2, 120_3, 120_4, 120_5, 120_6, and 120_7 may not be distinguished from each other.

The second connection gate electrode 130_2 may be disposed on the device isolation film 105. The second connection gate electrode 130_2 may be spaced apart from the first connection gate electrode 130_1 in the second direction D2. The plurality of gate electrodes 120 may be disposed between the first connection gate electrode 130_1 and the second connection gate electrode 130_2. The second connection gate electrode 130_2 may be spaced apart from the active region AP in the second direction D2. The second connection gate electrode 130_2 may not overlap with the active region AP in the third direction D3. The second connection gate electrode 130_2 may extend in the first direction D1. One end of the second connection gate electrode 130_2 may not protrude further than the first gate electrode 120_1 in the first direction D1. The other end of the second connection gate electrode 130_2 may not protrude further than the seventh gate electrode 120_7 in the first direction D1. The second connection gate electrode 130_2 may not overlap with the first source/drain region 150_1 and the eighth source/drain pattern 150_8 in the second direction D2.

The second connection gate electrode 130_2 may be connected to each of the first to seventh gate electrodes 120_1, 120_2, 120_3, 120_4, 120_5, 120_6, and 120_7. The second connection gate electrode 130_2 may be connected to one end of each of the first to seventh gate electrodes 120_1, 120_2, 120_3, 120_4, 120_5, 120_6, and 120_7 on the device isolation film 105. A boundary surface between the second connection gate electrode 130_2 and the first to seventh gate electrodes 120_1, 120_2, 120_3, 120_4, 120_5, 120_6, and 120_7 may not be distinguished from each other.

The first connection gate electrode 130_1 and the second connection gate electrode 130_2 may be formed by the same process as the first to seventh gate electrodes 120_1, 120_2, 120_3, 120_4, 120_5, 120_6, and 120_7. Upper surfaces of the first connection gate electrode 130_1 and the second connection gate electrode 130_2 may be disposed on the same plane as at least some of upper surfaces of the first to seventh gate electrodes 120_1, 120 2, 120_3, 120_4, 120_5, 120_6, and 120_7. For example, the upper surface of the first connection gate electrode 130_1 may be disposed on the same plane as the upper surface of the first gate electrode 120_1. In addition, a boundary surface between the first connection gate electrode 130_1 and the second connection gate electrode 130_2 and the first to seventh gate electrodes 120_1, 120_2, 120_3, 120_4, 120_5, 120_6, and 120_7 may not be distinguished from each other.

Each of the plurality of gate electrodes 120 and the connection gate electrodes 130_1 and 130_2 may include a conductive material. For example, each of the plurality of gate electrodes 120 and connection gate electrodes 130_1 and 130_2 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. However, embodiments are not limited thereto.

The gate insulating film 140 may be disposed on the active region AP. The gate insulating film 140 may be disposed between the substrate 100 and the plurality of gate electrodes 120. For example, the gate insulating film 140 may be disposed between a first gate electrode 120_1 and the upper surface of the substrate 100.

For example, the gate insulating film 140 may include a high-k material having a dielectric constant higher than that of silicon oxide, silicon oxynitride, silicon nitride, and silicon oxide. For example, the high-k material may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof, but embodiments are not limited thereto.

In one or more embodiments, a gate spacer 180 may be disposed on the substrate 100. The gate spacer 180 may extend along a side surface of each of the first to seventh gate electrodes 120_1, 120_2, 120_3, 120_4, 120_5, 120_6, and 120_7. The gate spacer 180 may include an insulating material. For example, the gate spacer 180 may include at least one of silicon oxynitride (SiON), silicon carbide (SiCN), and silicon oxynitride (SiOCN), but embodiments are not limited thereto.

A gate capping pattern may be formed on the upper surface of each of the first to seventh gate electrodes 120_1, 120_2, 120_3, 120_4, 120_5, 120_6, and 120_7. Also, an etch stop film may be formed on the gate spacer 180 and the gate capping pattern.

The plurality of source/drain regions 150 may be disposed in the active region AP. The plurality of source/drain regions 150 may be disposed on at least one side of the plurality of gate electrodes 120. Each of the plurality of source/drain regions 150 may extend in the second direction D2.

The plurality of source/drain regions 150 may include first to eighth source/drain regions 150_1, 150_2, 150_3, 150_4, 150_5, 150_6, 150_7, and 150_8.

The first source/drain region 150_1 may be disposed on one side of the first gate electrode 120_1, and the second source/drain region 150_2 may be disposed on the other side of the first gate electrode 120_1. The third source/drain region 150_3 may be disposed between the second gate electrode 120_2 and the third gate electrode 120_3. That is, the first to eighth source/drain regions 150_1, 150_2, 150_3, 150_4, 150_5, 150_6, 150_7, and 150_8 may be disposed alternately with the first to seventh gate electrodes 120_1, 120_2, 120_3, 120_4, 120_5, 120_6, and 120_7.

The first source/drain region 150_1 may be disposed between the first to seventh gate electrodes 120_1, 120_2, 120_3, 120_4, 120_5, 120_6, and 120_7 and the isolation impurity region 110 in the active region AP. The first source/drain region 150_1 may not overlap with the first connection gate electrode 130_1 and the second connection gate electrode 130_2 in the second direction D2. The eighth source/drain region 150_8 may be disposed between the first to seventh gate electrodes 120_1, 120_2, 120_3, 120_4, 120_5, 120_6, and 120_7 and the isolation impurity region 110 in the active region AP. The eighth source/drain region 150_8 may not overlap with the first connection gate electrode 130_1 and the second connection gate electrode 130_2 in the second direction D2.

The plurality of source/drain regions 150 may include impurities of a second conductivity type. For example, if the transistor formed on the substrate 100 is an NFET, the plurality of source/drain regions 150 may include n-type impurities. The n-type impurities may include, for example, phosphorus (P) or arsenic (As), but embodiments are not limited thereto.

In one or more embodiments, each of the plurality of source/drain regions 150 may include a heavily doped source/drain region 151 and a lightly doped source/drain region 152. The lightly doped source/drain region 152 may surround the heavily doped source/drain region 151.

The lightly doped source/drain region 152 may be closer to the gate electrode 120 than the heavily doped source/drain region 151. The doping concentration of the impurity in the heavily doped source/drain region 151 may be greater than the doping concentration of the impurity in the lightly doped source/drain region 152.

An interlayer insulating film 290 may be disposed on the substrate 100. The interlayer insulating film 290 may cover the substrate 100, the device isolation film 105, the plurality of source/drain regions 150, the plurality of gate electrodes 120, the first connection gate electrode 130_1, and the second connection gate electrode 130_2.

The interlayer insulating film 290 may include at least one of, for example, silicon oxide, silicon nitride, silicon oxynitride, and a low-k material having a dielectric constant lower than that of silicon oxide. For example, the low-k material may include at least one of flowable oxide (FOX), torene silazene (TOSZ), undoped silica glass (USG), borosilica glass (BSG), phosphosilica glass (PSG), borosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, and combinations thereof, but embodiments are not limited thereto.

The source/drain contact 210 may be disposed in and extend through the interlayer insulating film 290. The source/drain contact 210 may be disposed on the heavily doped source/drain region 151 of each of the plurality of source/drain regions 150. The source/drain contact 210 may be in contact with each of the plurality of source/drain regions 150. The source/drain contact 210 may be electrically connected to each of the plurality of source/drain regions 150.

The source/drain contact 210 may include a conductive material. For example, the source/drain contact 210 may include a metal such as aluminum (Al), copper (Cu), or tungsten (W), but embodiments are not limited thereto.

The gate contact 220 may be disposed in and extend through the interlayer insulating film 290. The gate contact 220 may be disposed on an upper surface of each of the plurality of gate electrodes 120. The gate contact 220 may be electrically connected to each of the plurality of gate electrodes 120.

The gate contact 220 may include a conductive material. For example, the gate contact 220 may include a metal such as aluminum (Al), copper (Cu), or tungsten (W), but embodiments are not limited thereto.

In a transistor in which a plurality of gate electrodes are disposed to be spaced apart from each other in one direction, the size of a depletion region may vary according to the position of each gate electrode. For example, a depletion region having a relatively small width may be formed on the first gate electrode 120_1 adjacent to the first vertical portion 110_V1 of the isolation impurity region 110. On the other hand, a depletion region having a relatively large width may be formed on the second gate electrode 120_2 spaced apart from the first vertical portion 110_V1 of the isolation impurity region 110. For this reason, the off-current characteristics of the second gate electrode 120_2 may deteriorate.

However, in a semiconductor device according to one or more embodiments of the present disclosure, a width of a central portion of the second to sixth gate electrodes 120_2, 120_3, 120_4, 120_5, and 120_6 may be greater than a width of the peripheral portion. For example, a width W1 of the first portion P1 of the second gate electrode 120_2 may be greater than a width W2 of the second portion P2. As a result, the off-current characteristics of the second gate electrode 120_2 can be improved. In addition, by forming the first connection gate electrode 130_1 and the second connection gate electrode 130_2 connected to the plurality of gate electrodes 120, the on-current characteristics of semiconductor devices can be improved.

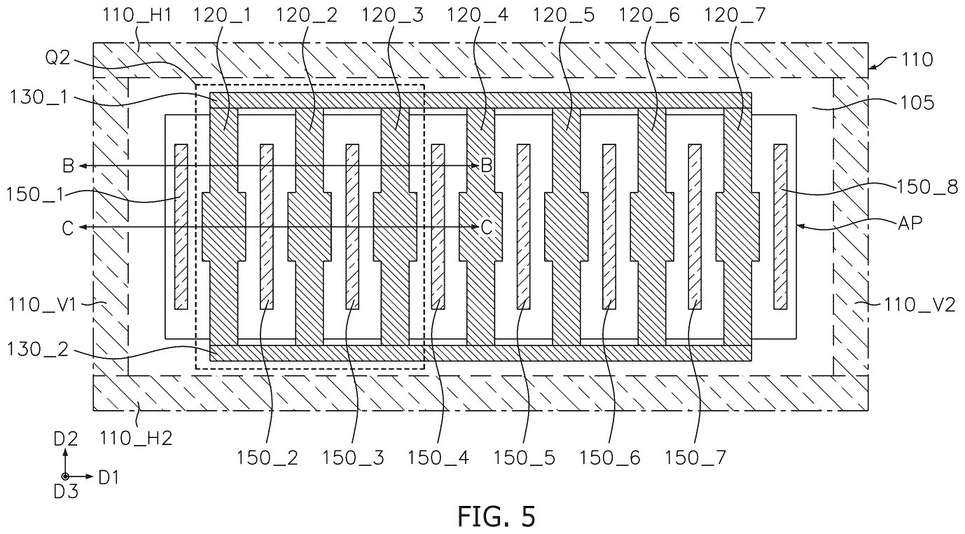

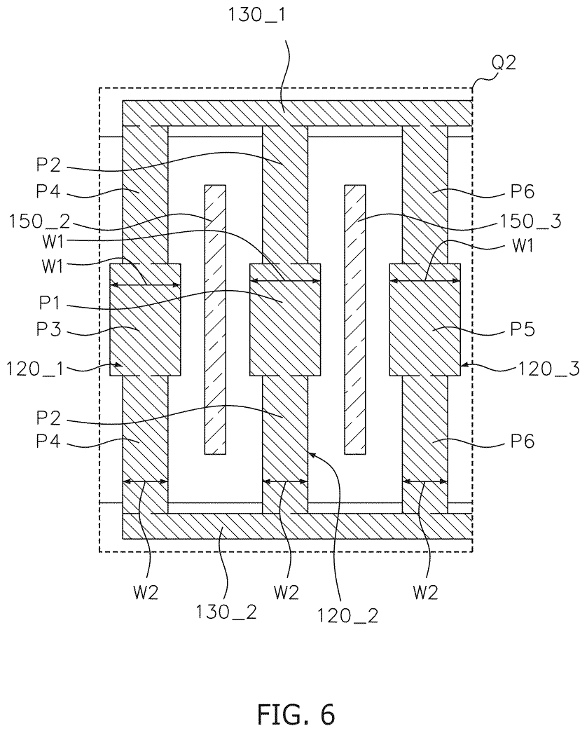

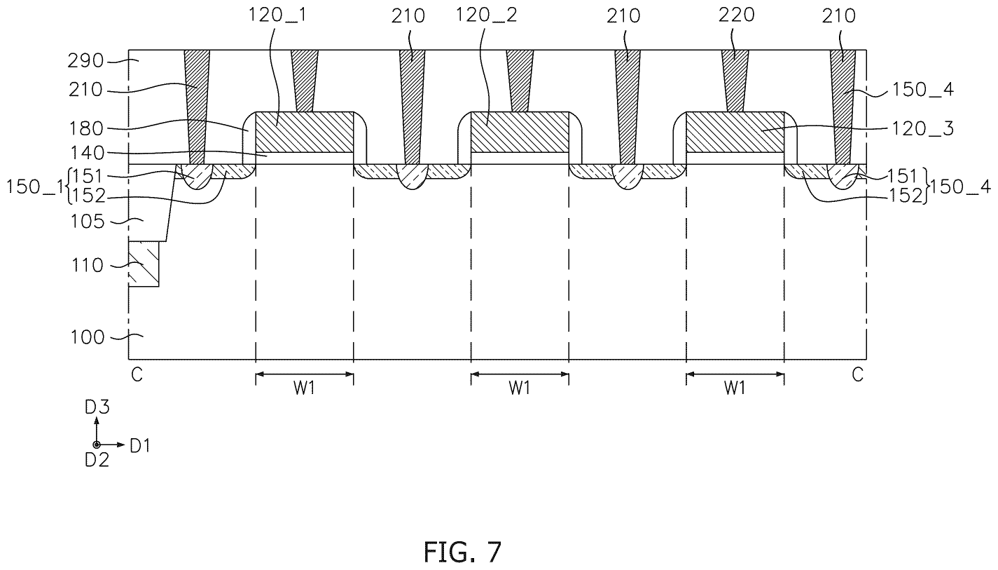

FIG. 5 is an example layout diagram provided to explain a semiconductor device according to one or more embodiments. FIG. 6 is an enlarged view provided to explain a region Q2 of FIG. 5. FIG. 7 is a cross-sectional view taken along line C-C of FIG. 5. For reference, a cross-sectional view taken along line B-B of FIG. 5 may be the same as that of FIG. 3. For convenience of description, different configurations from those described above in FIGS. 1 to 4 will be mainly described.

Referring to FIGS. 3 and 5 to 7, in the semiconductor device according to one or more embodiments, the width of the first gate electrode 120_1 in the first direction D1 may not be constant.

The plurality of gate electrodes 120 may include the first to seventh gate electrodes 120_1, 120_2, 120_3, 120_4, 120_5, 120_6, and 120_7. The first gate electrode 120_1 of the plurality of gate electrodes 120 may be disposed closest to the first vertical portion 110_V1 of the isolation impurity region 110. The first gate electrode 120_1 may be disposed between the first horizontal portion 110_H1 and the second horizontal portion 110_H2 of the isolation impurity region 110. The second gate electrode 120_2 may be spaced apart from the first gate electrode 120_1 in the first direction D1.

The first gate electrode 120_1 may include the third portion P3 and the fourth portion P4. The third portion P3 of the first gate electrode 120_1 may have the first width W1 in the first direction D1. The fourth portion P4 of the first gate electrode 120_1 may have the second width W2 in the first direction D1. The first width W1 may be greater than the second width W2.

The second gate electrode 120_2 may include the first portion P1 and the second portion P2. The first portion P1 of the second gate electrode 120_2 may have the first width W1 in the first direction D1. The second portion P2 of the second gate electrode 120_2 may have the second width W2 in the first direction D1. The shape of the second gate electrode 120_2 may be the same as the shape of the first gate electrode 120_1. Likewise, the shape of the seventh gate electrode 120_7 may be the same as the shape of the first gate electrode 120_1.

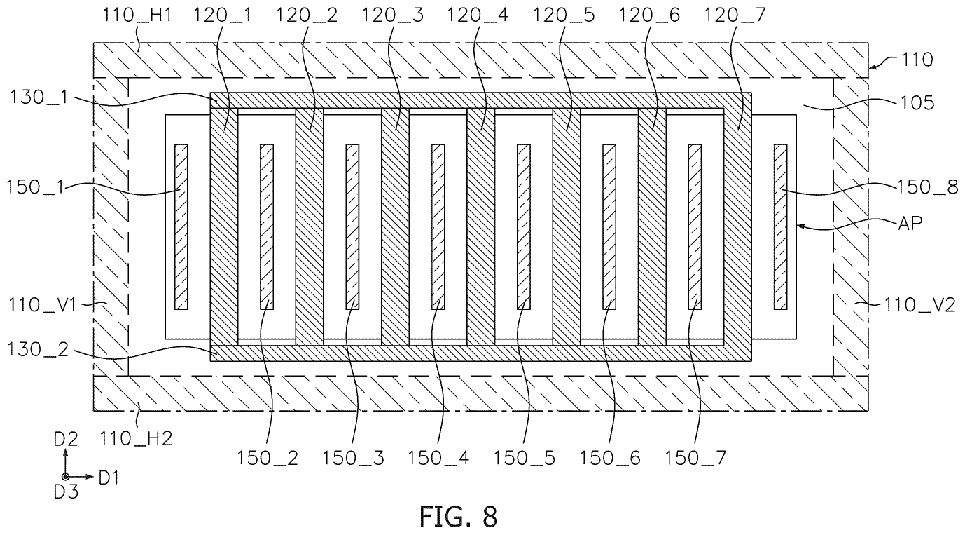

FIG. 8 is an example layout diagram provided to explain a semiconductor device according to one or more embodiments. For convenience of description, different configurations from those described above in FIGS. 1 to 4 will be mainly described.

Referring to FIG. 8, in the semiconductor device according to one or more embodiments, the width of each of the plurality of gate electrodes 120 may be constant in the first direction D1.

For example, the width of the first gate electrode 120_1 in the first direction D1 may be constant. The width of the second gate electrode 120_2 in the first direction D1 may be constant. The width of the first gate electrode 120_1 in the first direction D1 may be the same as the width of the second gate electrode 120_2 in the first direction D1. The widths of each of the first to seventh gate electrodes 120_1, 120_2, 120_3, 120_4, 120_5, 120_6, and 120_7 in the first direction D1 may be the same as each other.

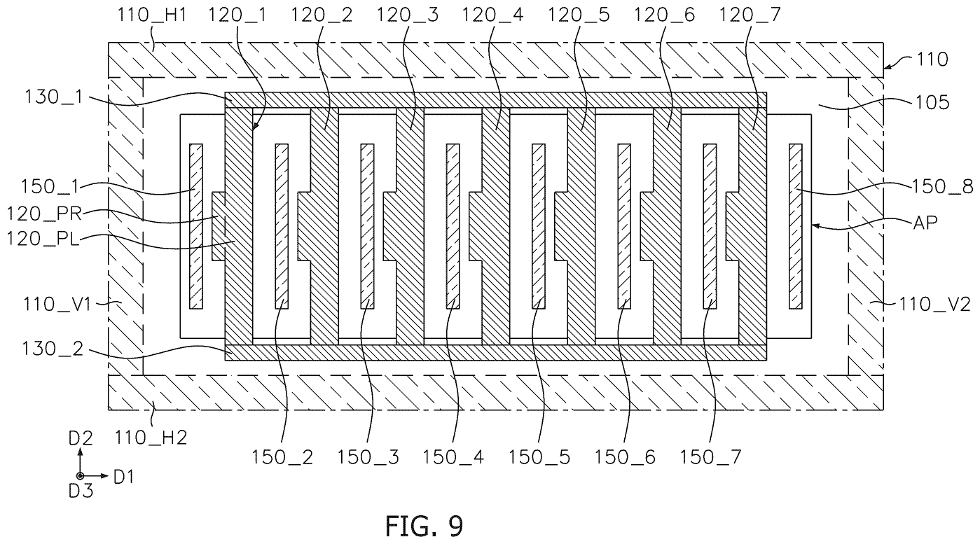

FIG. 9 is an example layout diagram provided to explain a semiconductor device according to one or more embodiments. For convenience of description, different configurations from those described above in FIGS. 1 to 4 will be mainly described.

Referring to FIG. 9, in the semiconductor device according to one or more embodiments, each of the plurality of gate electrodes 120 may include a plate portion and a protrusion portion. Descriptions of the shapes of each of the first to seventh gate electrodes 120_1, 120_2, 120_3, 120_4, 120_5, 120_6, and 120_7 may be the same. The first gate electrode 120_1 will be mainly described below.

The first gate electrode 120_1 may include a plate portion 120_PL extending in the second direction D2 and a protrusion portion 120_PR protruding from the plate portion 120 PL. A width of the plate portion 120_PL may be constant in the first direction D1. The protrusion portion 120_PR may protrude from the plate portion 120_PL toward the first source/drain region 150_1. The direction in which the protruding portions 120_PR of each of the first to seventh gate electrodes 120_1, 120_2, 120_3, 120_4, 120_5, 120_6, and 120_7 protrude may be the same.

Although it is illustrated that the first to seventh gate electrodes 120_1, 120_2, 120_3, 120_4, 120_5, 120_6, and 120_7 each include the plate portion 120_PL and the protrusion portion 120_PR, embodiments are not limited thereto. For example, the first gate electrode 120_1 and the seventh gate electrode 120_7 may include only the plate portion 120 PL.

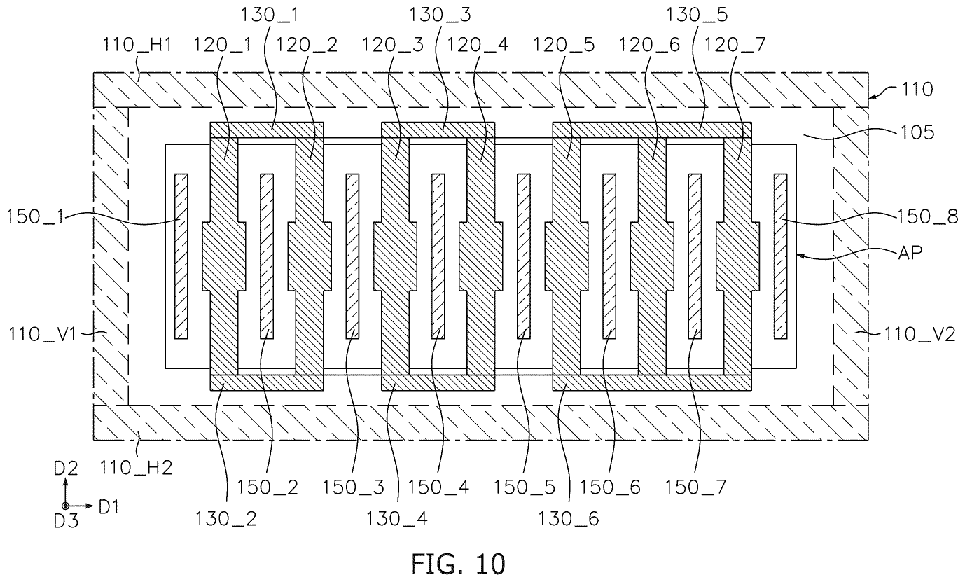

FIG. 10 is an example layout diagram provided to explain a semiconductor device according to one or more embodiments. For convenience of description, different configurations from those described above in FIGS. 1 to 4 will be mainly described.

Referring to FIG. 10, the semiconductor device according to one or more embodiments may further include third to sixth connection gate electrodes 130_3, 130_4, 130_5, and 130_6.

The first connection gate electrode 130_1 and the second connection gate electrode 130_2 may extend in the first direction D1. The first connection gate electrode 130_1 may be connected to one end of the first gate electrode 120_1 and one end of the second gate electrode 120_2. The second connection gate electrode 130_2 may be connected to the other end of the first gate electrode 120_1 and the other end of the second gate electrode 120_2. The first gate electrode 120_1 and the second gate electrode 120_2 may be disposed between the first connection gate electrode 130_1 and the second connection gate electrode 130_2.

The third connection gate electrode 130_3 and the fourth connection gate electrode 130 4 may extend in the first direction D1. The third connection gate electrode 130_3 may be connected to one end of the third gate electrode 120_3 and one end of the fourth gate electrode 120_4. The fourth connection gate electrode 130_4 may be connected to the other end of the third gate electrode 120_3 and the other end of the fourth gate electrode 120 4. The third gate electrode 120_3 and the fourth gate electrode 120_4 may be disposed between the third connection gate electrode 130_3 and the fourth connection gate electrode 130_4.

The fifth connection gate electrode 130_5 and the sixth connection gate electrode 130_6 may extend in the first direction D1. The fifth connection gate electrode 130_5 may be connected to one end of the fifth gate electrode 120_5, one end of the sixth gate electrode 120_6, and one end of the seventh gate electrode 120_7. The sixth connection gate electrode 130_6 may be connected to the other end of the fifth gate electrode 120_5, the other end of the sixth gate electrode 120_6, and the other end of the seventh gate electrode 120_7. The fifth gate electrode 120_5, the sixth gate electrode 120_6, and the seventh gate electrode 120_7 may be disposed between the fifth connection gate electrode 130_5 and the sixth connection gate electrode 130_6.

FIG. 10 illustrates that two gate electrodes 120 or three gate electrodes 120 of the plurality of gate electrodes 120 are connected to connection gate electrodes (e.g., the first and second connection gate electrodes 130_1 and 130_2 or the fifth and sixth connection gate electrodes 130_5 and 130_6), but embodiments are not limited thereto. For example, the number of the plurality of gate electrodes 120 connected by the connection gate electrode may vary.

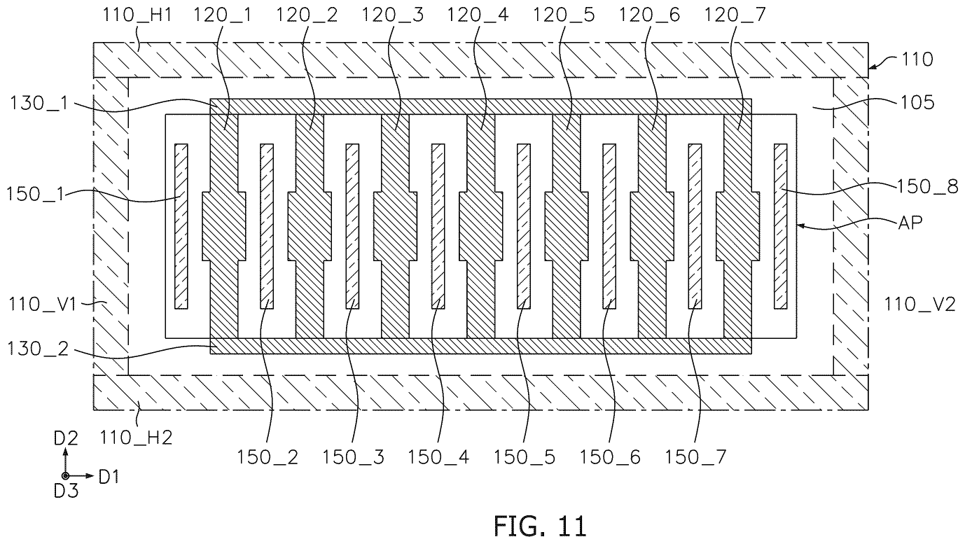

FIG. 11 is an example layout diagram provided to explain a semiconductor device according to one or more embodiments. For convenience of description, different configurations from those described above in FIGS. 1 to 4 will be mainly described.

Referring to FIG. 11, in the semiconductor device according to one or more embodiments, the first connection gate electrode 130_1 and the second connection gate electrode 130_2 may not be spaced apart from the active region AP. When viewed in a plan view, the first connection gate electrode 130_1 may not be spaced apart from the active region AP in the second direction D2, and the second connection gate electrode 130_2 may not be spaced apart from the active region AP in the second direction D2.

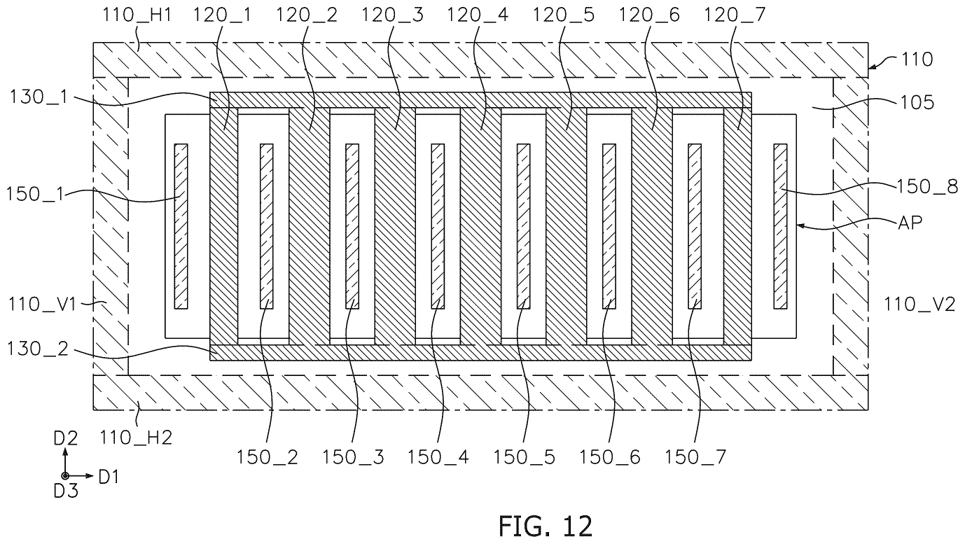

FIG. 12 is an example layout diagram provided to explain the semiconductor device according to one or more embodiments. For convenience of description, different configurations from those described above in FIGS. 1 to 4 will be mainly described.

Referring to FIG. 12, each of the plurality of gate electrodes 120 in the semiconductor device according to one or more embodiments may have a constant width in the first direction D1. The width of at least some of the gate electrodes 120 in the first direction D1 may be different from the width of the other gate electrodes 120 in the first direction D1. For example, the width of the first gate electrode 120_1 in the first direction D1 may be less than the width of the second gate electrode 120_2 in the first direction D1. The width of each of the second to sixth gate electrodes 120_2, 120_3, 120_4, 120_5, and 120 6 in the first direction D1 may be the same. The width of the first gate electrode 120_1 in the first direction D1 and the width of the seventh gate electrode 120_7 in the first direction D1 may be the same.

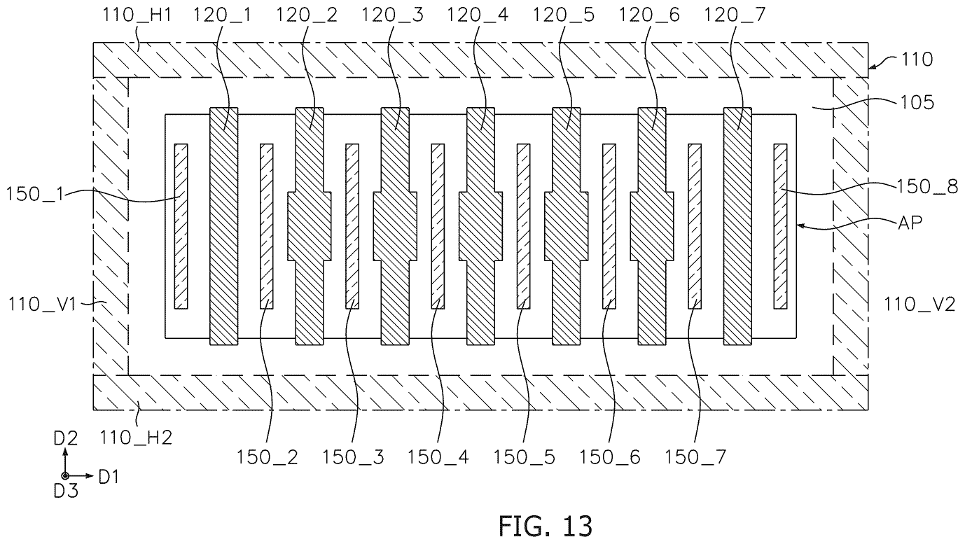

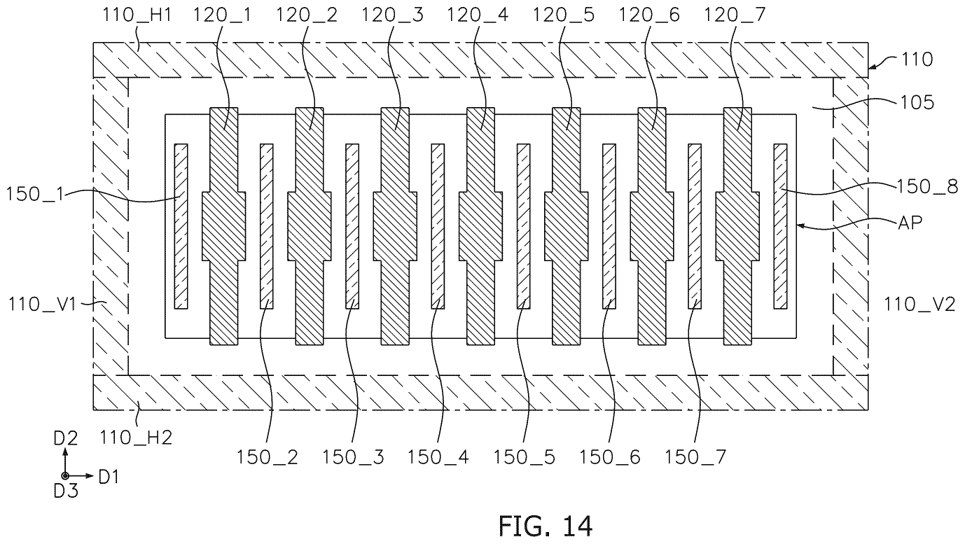

FIG. 13 is an example layout diagram provided to explain a semiconductor device according to one or more embodiments. FIG. 14 is an example layout diagram provided to explain a semiconductor device according to one or more embodiments. For convenience of description, different configurations from those described above in FIGS. 1 to 4 will be mainly described.

Referring to FIGS. 13 and 14, unlike FIG. 1, the semiconductor device according to one or more embodiments may not include the first connection gate electrode 130_1 and the second connection gate electrode 130_2.

Each of the first to seventh gate electrodes 120_1, 120_2, 120_3, 120_4, 120_5, 120_6, and 120_7 may extend in the second direction D2. The first to seventh gate electrodes 120_1, 120_2, 120_3, 120_4, 120_5, 120_6, and 120_7 may be spaced apart from each other in the first direction D1. The interlayer insulating film 290 may cover one and the other ends of each of the first to seventh gate electrodes 120_1, 120_2, 120_3, 120_4, 120_5, 120_6, and 120_7.

The first gate electrode 120_1 may be adjacent to one end of the active region AP. For example, the first gate electrode 120_1 of the plurality of gate electrodes 120 may be disposed closest to the first vertical portion 110_V1 of the isolation impurity region 110. The first gate electrode 120_1 may be disposed between the first horizontal portion 110_H1 and the second horizontal portion 110_H2 of the isolation impurity region 110.

The second gate electrode 120_2 may be spaced apart from the first gate electrode 120_1 in the first direction D1. The second gate electrode 120_2 may be disposed between the first horizontal portion 110_H1 and the second horizontal portion 110_H2 of the isolation impurity region 110. The second gate electrode 120_2 may be disposed between the first gate electrode 120_1 and the third gate electrode 120_3.

The second gate electrode 120_2 may include portions having different widths in the first direction D1. For example, the second gate electrode 120_2 may include the first portion P1 having the first width W1 and the second portion P2 having the second width W2, as illustrated in FIG. 1.

As illustrated in FIG. 13, the first gate electrode 120_1 and the seventh gate electrode 120_7 may have the same width in the first direction D1. The width of the first gate electrode 120_1 in the first direction D1 may be the same as the width of the second portion P2 of the second gate electrode 120_2.

In another aspect, as illustrated in FIG. 14, the first gate electrode 120_1 and the seventh gate electrode 120_7 may include portions having different widths. The shapes of the first gate electrode 120_1 and the seventh gate electrode 120_7 may be the same as that of the second gate electrode 120_2.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor device comprising:
a substrate;
an active region on the substrate and extending in a first direction;
a device isolation film around the active region in the substrate;
a first gate electrode extending on the active region in a second direction that intersects the first direction;
a second gate electrode extending on the active region in the second direction and spaced apart from the first gate electrode in the first direction;
a first connection gate electrode extending in the first direction and connected to a first end of the first gate electrode and a first end of the second gate electrode; and
a source/drain region in the active region at a side of the first gate electrode.

2. The semiconductor device according to claim 1, further comprising a second connection gate electrode extending in the first direction and connected to a second end of the first gate electrode and a second end of the second gate electrode, and,
wherein the first connection gate electrode and the second connection gate electrode are spaced apart from each other in the second direction.

3. The semiconductor device according to claim 1, wherein the second gate electrode comprises a first portion having a first width in the first direction and a second portion having a second width in the first direction, and
wherein the first width is greater than the second width.

4. The semiconductor device according to claim 3, wherein the second portion of the second gate electrode is in contact with the first connection gate electrode.

5. The semiconductor device according to claim 3, wherein the first gate electrode has the second width in the first direction.

6. The semiconductor device according to claim 3, wherein the first gate electrode comprises a third portion having the first width in the first direction and a fourth portion having the second width in the first direction, and
wherein the fourth portion of the first gate electrode overlaps the second portion of the second gate electrode in the first direction.

7. The semiconductor device according to claim 1, wherein the first connection gate electrode is spaced apart from the active region in the second direction.

8. The semiconductor device according to claim 1, wherein the first connection gate electrode is on the device isolation film, and
wherein an upper surface of the first connection gate electrode is on the same plane as an upper surface of the first gate electrode.

9. The semiconductor device according to claim 3, further comprising a third gate electrode extending on the active region in the second direction and spaced apart from the second gate electrode in the first direction,
wherein a first end of the third gate electrode is connected to the first connection gate electrode.

10. The semiconductor device according to claim 9, wherein the third gate electrode comprises a fifth portion having the first width in the first direction and a sixth portion having the second width in the first direction.

11. The semiconductor device according to claim 1, further comprising a gate insulating film between the first gate electrode and the substrate and between the second gate electrode and the substrate.

12. A semiconductor device comprising:
a substrate;
an active region extending on the substrate in a first direction;
a device isolation film around the active region in the substrate;
an isolation impurity region in the substrate under the device isolation film and around the active region, wherein the isolation impurity region comprises a first horizontal portion extending in the first direction, a second horizontal portion extending in the first direction, a first vertical portion extending in a second direction that intersects the first direction, and a second vertical portion extending in the second direction;
a plurality of gate electrodes extending on the active region in the second direction and spaced apart from each other in the first direction;
a first connection gate electrode extending in the first direction and connected to at least a portion of the plurality of gate electrodes; and
a second connection gate electrode extending in the first direction, connected to at least a portion of the plurality of gate electrodes, and spaced apart from the first connection gate electrode in the second direction.

13. The semiconductor device according to claim 12, further comprising a plurality of source/drain regions in the active region, between adjacent gate electrodes of the plurality of gate electrodes, and between the isolation impurity region and the plurality of gate electrodes,
wherein the first connection gate electrode does not overlap the plurality of source/drain regions in the second direction.

14. The semiconductor device according to claim 12, wherein at least one of the plurality of gate electrodes comprises a first portion having a first width in the first direction and a second portion having a second width in the first direction, and
wherein the first width is greater than the second width.

15. The semiconductor device according to claim 14, wherein a distance from the first connection gate electrode to the first portion is the same as a distance from the second connection gate electrode to the first portion.

16. The semiconductor device according to claim 12, wherein the plurality of gate electrodes comprise a first gate electrode and a second gate electrode spaced apart from the first gate electrode in the first direction,
wherein the first connection gate electrode is connected to a first end of the first gate electrode and a first end of the second gate electrode, and
wherein the second connection gate electrode is connected to a second end of the first gate electrode and a second end of the second gate electrode.

17. The semiconductor device according to claim 16, wherein a width of the first gate electrode in the first direction is constant, and
wherein a width of at least a portion of the second gate electrode in the first direction is different from the width of the first gate electrode in the first direction.

18. The semiconductor device according to claim 16, wherein the second gate electrode comprises a first portion having a first width in the first direction and a second portion having a second width in the first direction, and
wherein the first gate electrode comprises a third portion having the first width in the first direction and a fourth portion having the second width in the first direction.

19. The semiconductor device according to claim 12, wherein the first connection gate electrode does not overlap the active region in a third direction, and
wherein the third direction intersects the first direction and the second direction, respectively.

20. A semiconductor device comprising:
a substrate;
an active region extending on the substrate in a first direction;
a device isolation film around the active region in the substrate;
an isolation impurity region in the substrate under the device isolation film and around the active region, wherein the isolation impurity region comprises a first horizontal portion extending in the first direction, a second horizontal portion extending in the first direction, a first vertical portion extending in a second direction that intersects the first direction, and a second vertical portion extending in the second direction;
a first gate electrode extending on the active region in the second direction and adjacent to the first vertical portion of the isolation impurity region;
a second gate electrode extending on the active region in the second direction and spaced apart from the first gate electrode in the first direction;
a first connection gate electrode extending in the first direction and connected to a first end of the first gate electrode and a first end of the second gate electrode;
a second connection gate electrode extending in the first direction and connected to a second end of the first gate electrode and a second end of the second gate electrode; and
a source/drain region between the first gate electrode and the first vertical portion of the isolation impurity region,
wherein the second gate electrode comprises a first portion having a first width in the first direction and a second portion having a second width in the first direction, and
wherein the first width is greater than the second width.

21. (canceled)
